(19) United States
(12) Patent Application Publication
(10) Pub. No.: US 2006/0138526 A1
(43) Pub. Date: Jun. 29, 2006

(54) Semiconductor device and method of manufacturing the same

(76) Inventor: Mutsumi Okajima, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/358,078

(22) Filed: Feb. 22, 2006

Related U.S. Application Data
(62) Division of application No. 10/762,542, filed on Jan. 23, 2004.

(30) Foreign Application Priority Data
Oct. 20, 2003 (JP) 2003-359375

(51) Int. Cl. H01L 29/788

(52) U.S. Cl. 257/315

(57) ABSTRACT

Disclosed is a semiconductor device comprising a first conductive film serving as a floating gate and formed on a semiconductor film via a first gate insulating film, a second conductive film serving as a control gate and formed on the first conductive film via a second gate insulating film, and a third conductive film buried in a contact hole formed by removing a part of the second conductive film and second gate insulating film so as to reach an upper surface of the first conductive film from an upper surface of the second conductive film.

### CROSS-REFERENCE TO RELATED APPLICATIONS

This application is a Divisional of U.S. patent application Ser. No. 10/762,542, filed Jan. 23, 2004, and is based upon and claims the benefit of priority from the prior Japanese Patent Application No. 2003-359375, filed Oct. 20, 2003. The entire contents of these applications are incorporated herein by reference.

### BACKGROUND OF THE INVENTION

1. Field of the Invention

The present invention relates to a semiconductor device having a stack-gate nonvolatile semiconductor memory in which a floating gate and a control gate are stacked. More particularly, the present invention relates to a semiconductor device improved in the contact portion between the floating gate and the control gate.

2. Description of the Related Art

Conventionally, a NAND cell unit used in a NAND type nonvolatile semiconductor memory is formed by connecting a plurality of nonvolatile semiconductor memory cells in series and connecting a selective transistor to both edges of the serial memory cells. Each of the serial memory cells has a two-layer gate structure (stack gate structure), which is constructed by forming a floating gate on a semiconductor substrate via a first gate insulating film and forming a control gate on the floating gate via a second gate insulating film. The selective transistor has also a two-layer gate structure since it is formed simultaneously with the memory cells. However, in the selective transistor, since its floating gate must be electrically in contact with the control gate, a gate insulating film formed on the floating gate of the selective transistor region is lithographically removed before a conductive film serving as the control gate is formed (see, for example, Japanese Patent Application KOKAI Publication No. 2002-176114).

In the lithography for partially removing the gate insulating film from the floating gate, alignment of the lithographic pattern is performed based on the element-isolating region previously formed. On the other hand, in the lithography for forming a gate-wiring pattern, the lithographic pattern is aligned based on the element-isolating region. Therefore, the lithographic pattern for forming an open portion in the insulating film between the gates is not directly aligned with the lithographic pattern for forming the gate wiring. Therefore, a wide alignment margin is required.

Accordingly, in the prior art, when not only a memory cell but also a selective transistor and a peripheral transistor are reduced in size, and thereby the open portion of the insulating film between the gates in the selective transistor and peripheral transistor becomes small, the alignment margin for forming the open portion in the lithographic process becomes extremely narrow. In the worst case, it may be difficult to perform lithography. To ensure the lithographic alignment margin, the sizes of selective transistor and the peripheral transistor cannot be reduced; with the result that further miniaturization of the device is limited (see, for example, Japanese Patent Application KOKAI Publication No. 2002-176114).

As described, in the prior technique, lithographic pattern for forming an open portion in the insulating film between a floating gate and a control gate is not directly aligned with that for forming the gate wiring. For this reason, a wide alignment margin must be required when the open portion is lithographically formed, preventing miniaturization of the semiconductor device.

### BRIEF SUMMARY OF THE INVENTION

According to an aspect of the present invention, there is provided a semiconductor device comprising:

a first conductive film serving as a floating gate and formed on a semiconductor film via a first gate insulating film;

a second conductive film serving as a control gate and formed on the first conductive film via a second gate insulating film; and

a third conductive film buried in a contact hole formed by removing a part of the second conductive film and second gate insulating film so as to reach an upper surface of the first conductive film from an upper surface of the second conductive film.

According to another aspect of the present invention, there is provided a semiconductor device comprising:

a nonvolatile semiconductor memory cell having a stacked gate formed by stacking a floating gate and a control gate above a semiconductor substrate; and

a transistor other than the memory cell, formed by stacking a first conductive film serving as the floating gate and a second conductive film serving as the control gate and bringing the first and second conductive films electrically into contact with each other, thereby forming gate wiring,

in which, in the transistor portion other than the memory cell, a third conductive film is buried in a contact hole formed so as to reach an upper surface of the first conductive film from an upper surface of the second conductive film.

According to still another aspect of the present invention, there is provided a method of manufacturing a semiconductor device, comprising:

stacking a first gate insulating film, a first conductive film serving as a floating gate, a second gate insulating film, and a second conductive film serving as a control gate on a semiconductor substrate, thereby forming a gate wiring pattern of a stacked gate structure;

removing part of the second conductive film and the second gate insulating film, thereby forming a contact hole reaching an upper surface of the first conductive film from an upper surface of the second conductive film; and

burying a third conductive film in the contact hole.

According to a further aspect of the present invention, there is provided a method of manufacturing a semiconductor device, comprising:

forming a first conductive film serving as a floating gate on a semiconductor substrate via a first gate insulating film;

selectively etching the first conductive film serving as the floating gate so as to remove at least an unnecessary portion in a gate-width direction of the floating gate,

forming a second conductive film serving as a control gate on the substrate and on the first conductive film via a second gate insulating film;

selectively etching the second conductive film together with the first conductive film, thereby forming a gate wiring pattern for each of a nonvolatile semiconductor memory cell and a transistor other than the memory cell;

selectively etching the second conductive film and second gate insulating film by lithography in accordance with the gate wiring pattern in the transistor other than the memory cell, thereby forming a contact hole reaching an upper surface of the first conductive film from an upper surface of the second conductive film; and

burying a third conductive film in the contact hole.

### BRIEF DESCRIPTION OF THE SEVERAL VIEWS OF THE DRAWING

FIG. 1 is a plan view showing a NAND type nonvolatile semiconductor memory after gate wiring is formed;

FIGS. 2A to 2H are sectional views of the NAND type nonvolatile semiconductor memory taking along the line X-X′ of FIG. 1 and showing steps of forming an element isolating region;

FIGS. 3A to 3K are sectional views of the NAND type nonvolatile semiconductor memory taking along the line Y-Y′ of FIG. 1 and showing the steps of forming gate wiring;

FIGS. 4A to 4M are sectional views showing the manufacturing steps of a NAND type nonvolatile semiconductor memory according to a first embodiment;

FIGS. SA to 5H are sectional views showing the manufacturing steps of a NAND type nonvolatile semiconductor memory according to a second embodiment; and

FIGS. 6A to 6I are sectional views showing the manufacturing steps of a NAND type nonvolatile semiconductor memory according to a third embodiment.

### DETAILED DESCRIPTION OF THE INVENTION

A method of manufacturing a general NAND type nonvolatile semiconductor memory will be explained before describing the embodiments of the present invention. More specifically, from a step of forming an element isolating region, to a step of planarizing the surface of the device including a step of forming gate wiring, will be explained.

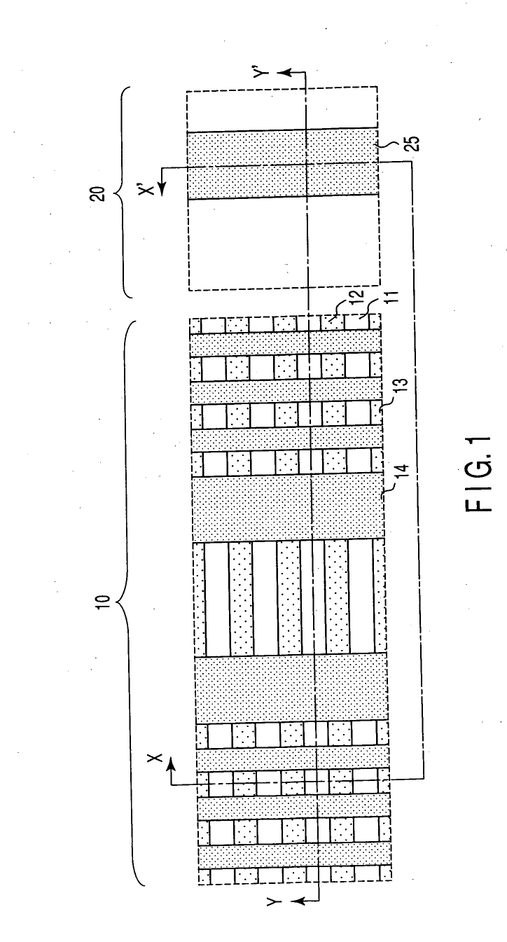

FIG. 1 shows a schematic plan view of a NAND type nonvolatile semiconductor memory after a control gate is formed. In FIG. 1, an element region 11 and an element isolating region 12 are formed in a line and space pattern. In the element region 11, a plurality of memory cells 13 are connected in series to form a memory cell unit. Generally, in the NAND type nonvolatile semiconductor memory, two selective transistors 14 are arranged at intervals of 16 or 32 lines of the gate wiring of a transistor of the memory cell 13. In a peripheral circuit region 20, the pattern of a peripheral transistor 25 is formed.

In the first step, a method of forming an element isolating region of a NAND type nonvolatile semiconductor device will be explained below with reference to the sectional view taken along the line X-X′ of FIG. 1.

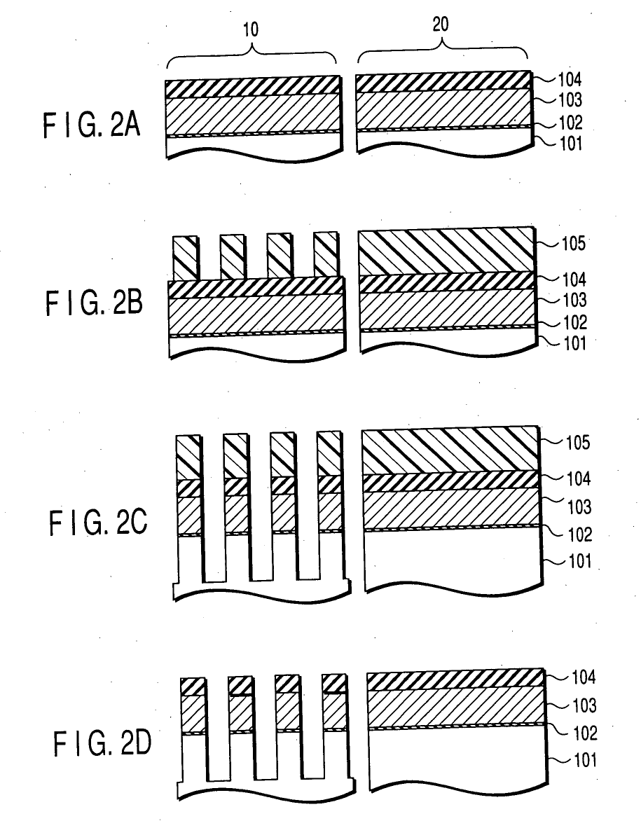

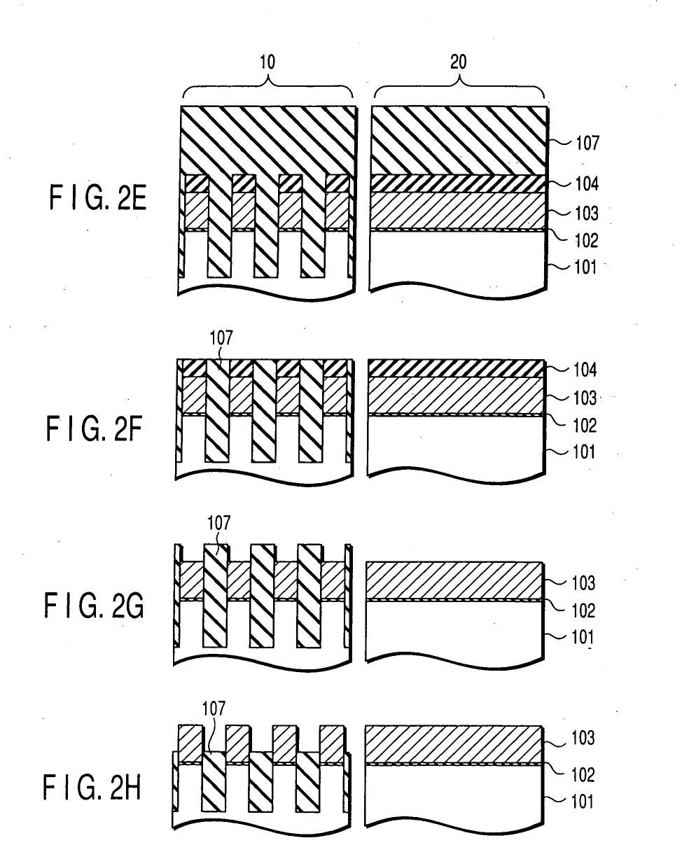

As shown in FIG. 2A, a tunnel insulating film (first gate insulating film) 102 of 10 nm thick is formed on a silicon substrate 101 by a thermal oxidation method. Subsequently, a phosphorous-doped polysilicon film 103 of 140 nm thick serving as a floating gate, is deposited by a low-pressure chemical vapor deposition (an LP-CVD method) method. Thereafter, a silicon nitride film 104 of 70 nm thick is deposited by the same an LP-CVD method.

Next, as shown in FIG. 2B, a resist pattern 105 for use in forming element isolating regions is lithographically formed on the silicon nitride film 104. Subsequently, as shown in FIG. 2C, the silicon nitride film 104, phosphorus-doped polysilicon film 103, and tunnel insulating film 102 are selectively dry-etched with the resist pattern 105 used as a mask, and then, the silicon substrate 101 is etched to a depth of 200 nm from the surface. Thereafter, as shown in FIG. 2D, the resist pattern 105 is removed by an ashing method. As a result, grooves for the element isolating regions are formed in the surface of the silicon substrate 101.

In the next step, as shown in FIG. 2E, a silicon oxide film 107 of 500 nm thick is deposited over the resultant structure by a plasma chemical vapor deposition (P-CVD) method. Subsequently, as shown in FIG. 2F, the silicon oxide film 107 is ground by a chemical mechanical polishing (CMP) method with the silicon nitride film 104 used as a stopper. As a result, the surface of the device is planarized and simultaneously the silicon oxide film 107 is buried in the element isolating regions.

Next, as shown in FIG. 2G, after the silicon nitride film 104 is etched away by a wet-etching method, the silicon oxidation film 107 buried in the groove of the element isolating region is removed by a dry etching method to a depth of 100 nm from the surface of the phosphorus doped polysilicon film 103, as shown in FIG. 2H. This is performed to increase the capacitance between the floating gate and the control gate.

In the aforementioned steps, the silicon oxide film 107 is buried in the element isolating region 12 and the phosphorus-doped polysilicon film 103 serving as a floating gate later is formed on the element region 11 in a self-alignment manner.

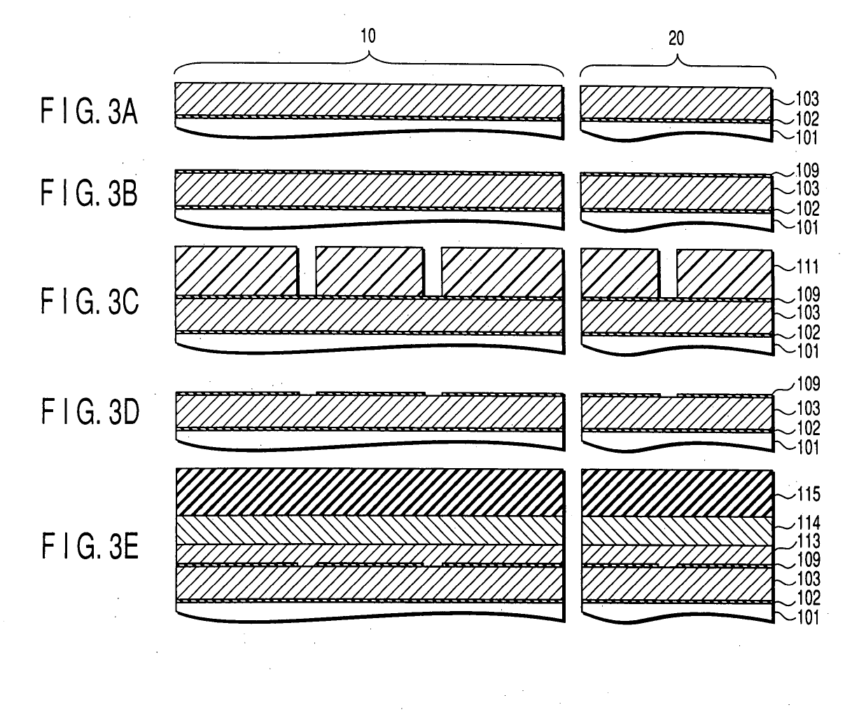

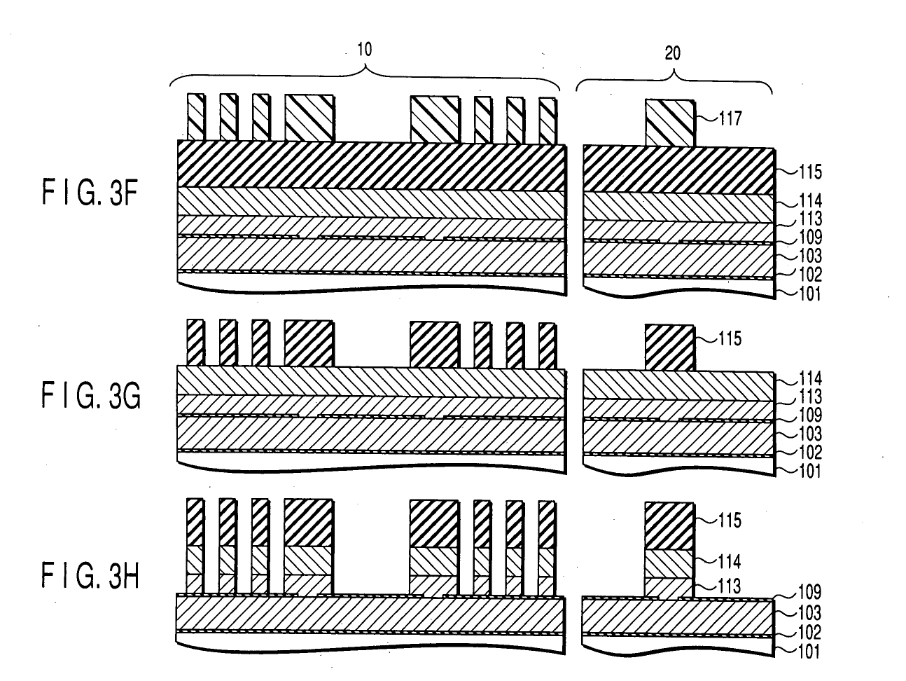

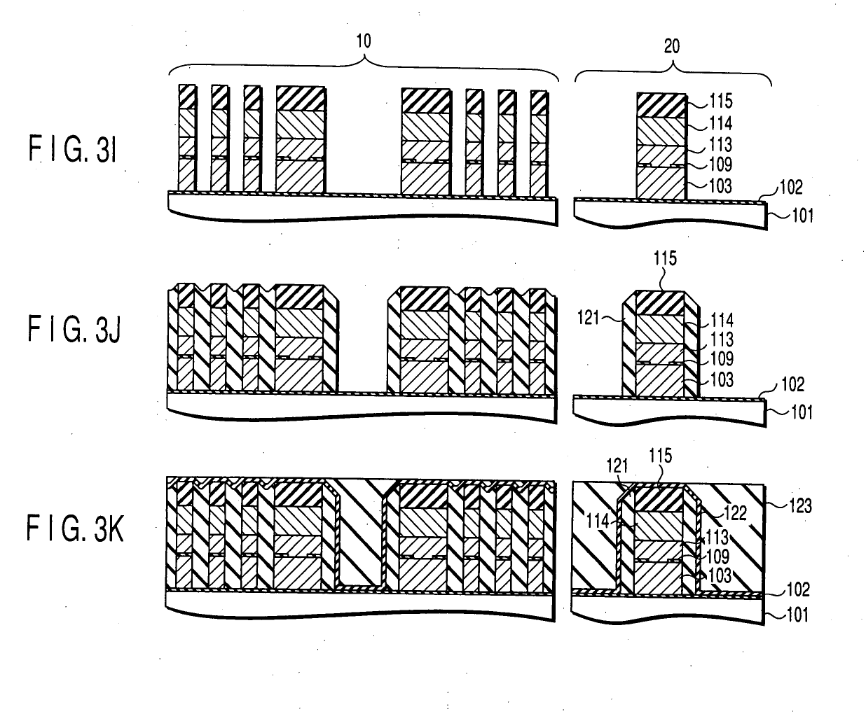

Now, the steps from forming gate wiring to planarizing the surface of the device will be explained with reference to the sectional view taken along the Y-Y′ line of FIG. 1. FIG. 3A shows the sectional view of the semiconductor memory taken along the Y-Y′ line after the step of forming element isolation regions. As described previously, the phosphorus doped polysilicon film 103 is deposited on the element region 11 via the tunnel insulating film 102.

Subsequently, as shown in FIG. 3B, to insulate the floating gate from the control gate, an interlayer insulating film (second gate insulating film) 109 of 15 nm thick is deposited by an LP-CVD method. The interlayer insulating film 109 used herein is an ONO film formed of a silicon oxide film, a silicon nitride film, and silicon oxide film sequentially stacked.

Subsequently, as shown in FIG. 3C, a resist pattern 111 for removing the ONO film 109 from the selective transistor region and peripheral transistor region is lithographically formed. Thereafter, as shown in FIG. 3D, the ONO film 109 not covered with the resist pattern is removed by a dry etching method and then the resist pattern 111 is removed by an ashing method.

Next, as shown in FIG. 3E, a phosphorus-doped polysilicon film 113 of 80 nm thick serving as the control gate, is deposited. Furthermore, to reduce the resistance of the control gate, a tungsten silicide film 114 of 100 nm thick is deposited by a sputtering method, and then, a silicon nitride film 115 of 200 nm thick is deposited by an LP-CVD method.

Subsequently, as shown in FIG. 3F, a resist pattern 117 for processing gate wiring is lithographically formed. Subsequently, as shown in FIG. 3G, the silicon nitride film 115 is dry-etched, and then the resist pattern 117 is removed by an ashing method.

As shown in FIG. 3H, the tungsten silicide film 114 and phosphorus doped polysilicon film 113 are dry-etched with the silicon nitride film 115 used as a mask. During this dry etching step, the ONO film 109 acts as a stopper.

Next, as shown in FIG. 3I, the ONO film 109 is also dry-etched and further the phosphorus-doped polysilicon film 103 is dry-etched followed by forming a source and drain diffusion layer (not shown).

By the steps mentioned above, the memory cells 13, selective transistors 14, and peripheral transistor 25 of a NAND type nonvolatile semiconductor memory are formed as shown in FIG. 1. In the selective transistors 14 and the peripheral transistor 25, the floating gate and the control gate are electrically in contact with each other through the open portion of the ONO film 109. With this structure, it is possible to form a gate wiring pattern of the selective transistor 14 virtually in perpendicular to the line and space pattern of the element region 11 and element isolating region 12. In addition, the resistance of the gate wiring of the peripheral transistor 25 can be reduced more than the one constructed of the floating gate alone.

After the step shown in FIG. 3I, a silicon oxide film 121 of 60 nm thick is deposited by an LP-CVD method, as shown in FIG. 3J. Subsequently, the entire construct is etched back by dry etching with the silicon substrate 101 used as a stopper and the surface of the silicon substrate 101 thus exposed is oxidized to a depth of 10 nm by heat treatment performed in an oxidative atmosphere.

Subsequently, a silicon nitride film 122 of 20 nm thick is deposited by an LP-CVD method, and then, a silicon oxide film 123 of 700 nm thick is further deposited by an LP-CVD method. Subsequently, the silicon oxide film 123 is ground by a CMP method with the silicon nitride film 122 used as a stopper, thereby planarizing the surface of the device. In this manner, processing from the step of forming gate wiring to the step of planarizing the surface of the device is completed, as shown in FIG. 3K.

In the aforementioned manufacturing technique, the gate wiring of the selective transistors and the peripheral transistor is formed as follows. After the element isolating region is formed, the ONO film 109 is deposited on the conductive film 103 serving as a floating gate, and then, an open portion is formed in part of the ONO film 109 by a lithographic method or dry-etching method. Subsequently, the conductive film 113 serving as a control gate is deposited, and thereafter, a gate wiring pattern is lithographically formed. The alignment of the lithographic pattern for forming the open portion is performed based on the element isolating region. Furthermore, the alignment of the lithographic pattern for forming the gate wiring is performed based on the element isolating region. Therefore, the lithographic pattern for forming the opening portion is not directly aligned with that for forming gate wring. For this reason, a wide alignment margin is required.

More specifically, the wide alignment margin is required for the following reasons. If the degree of misalignment is large, there may be a portion in which the ONO film 109 serving as the etching stopper is not present during the dry etching performed in the step of FIG. 3H. As a result, the phosphorus-doped polysilicon film 103 serving as the floating gate is inevitably etched. Accordingly, when the phosphorus-doped polysilicon film 103 of the floating gate is etched in the next step, it becomes difficult to stop etching by the tunnel insulating film 102. As a result, the silicon substrate 101 is inevitably etched.

To overcome such a problem, the following structure and manufacturing method are employed in the embodiments of the present invention.

### First Embodiment

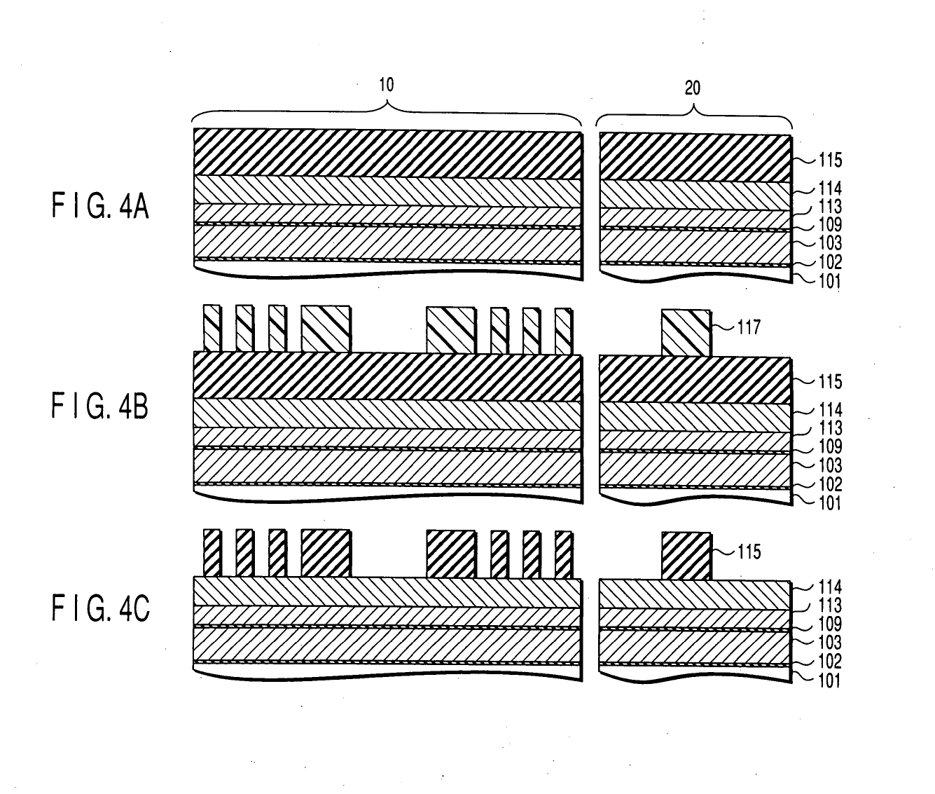

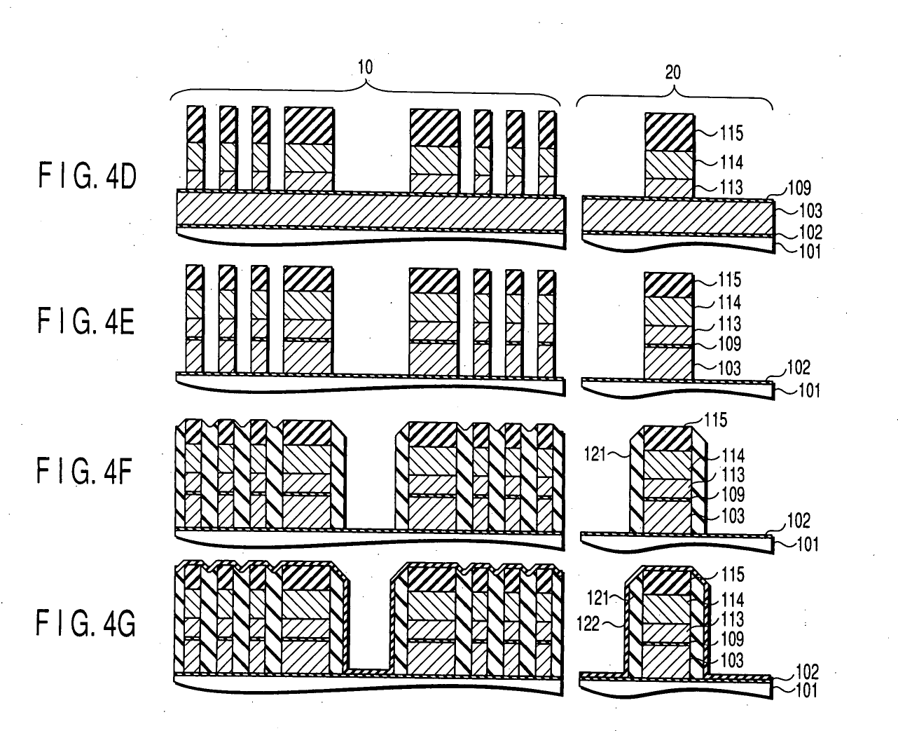

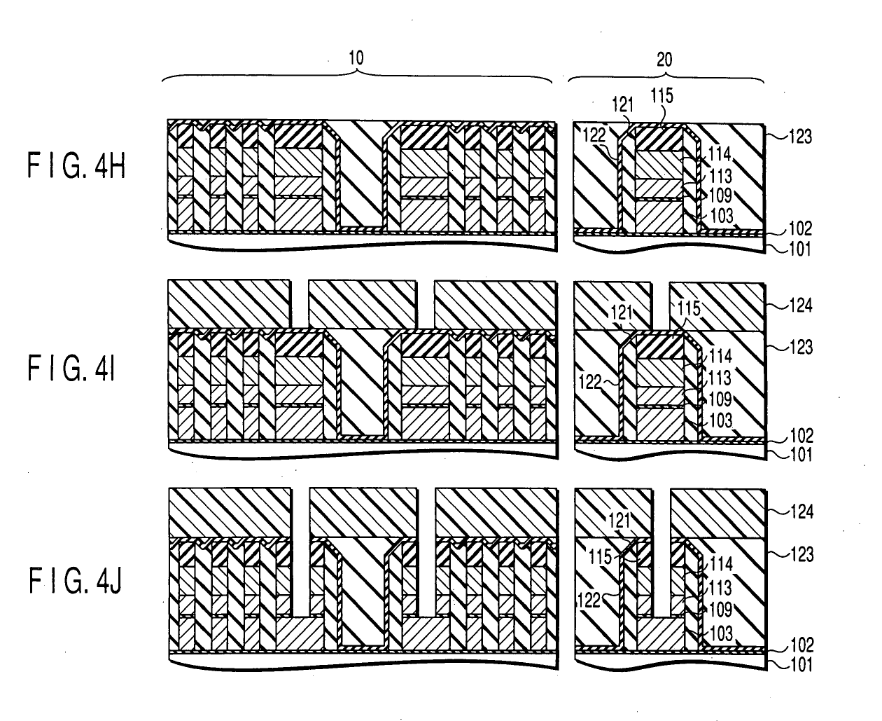

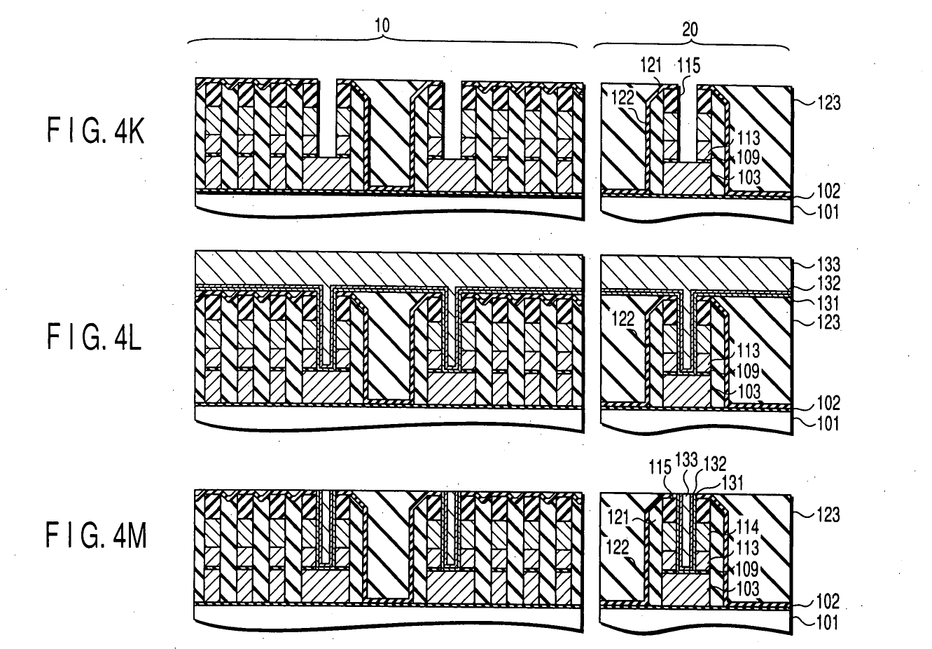

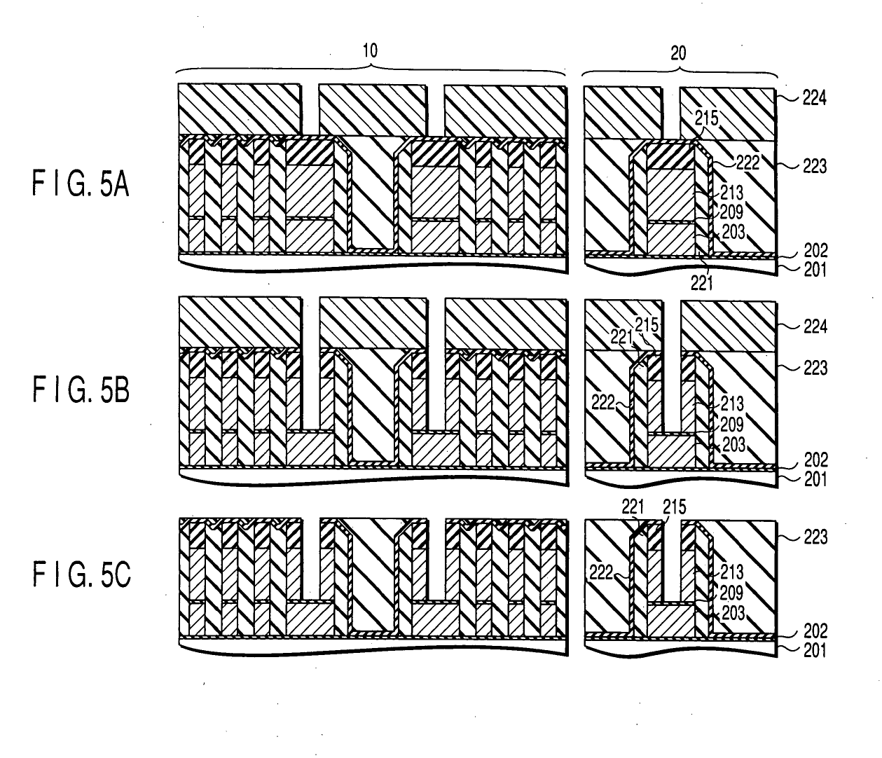

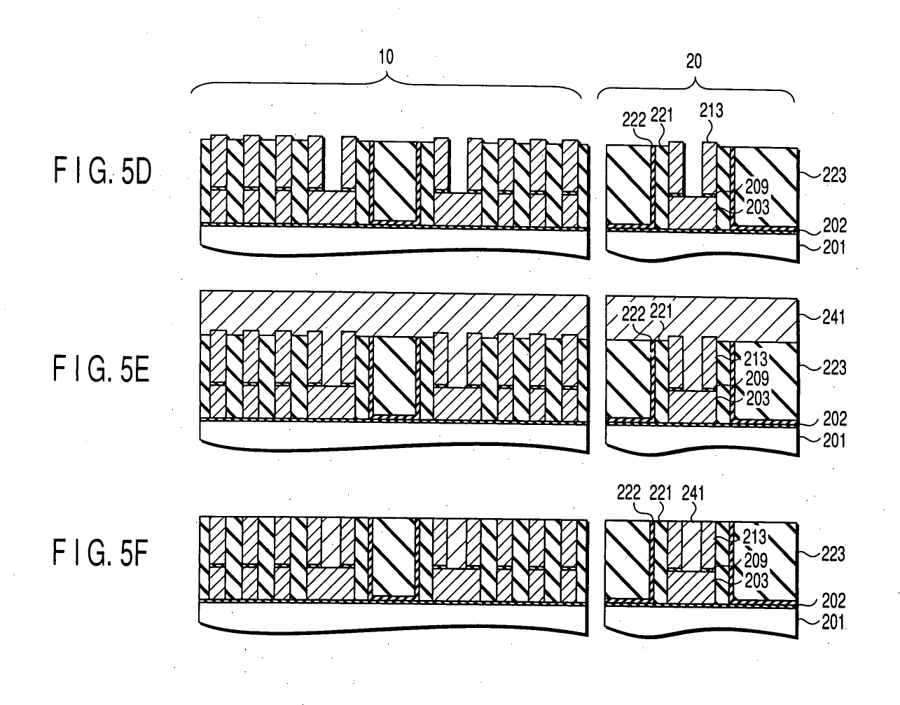

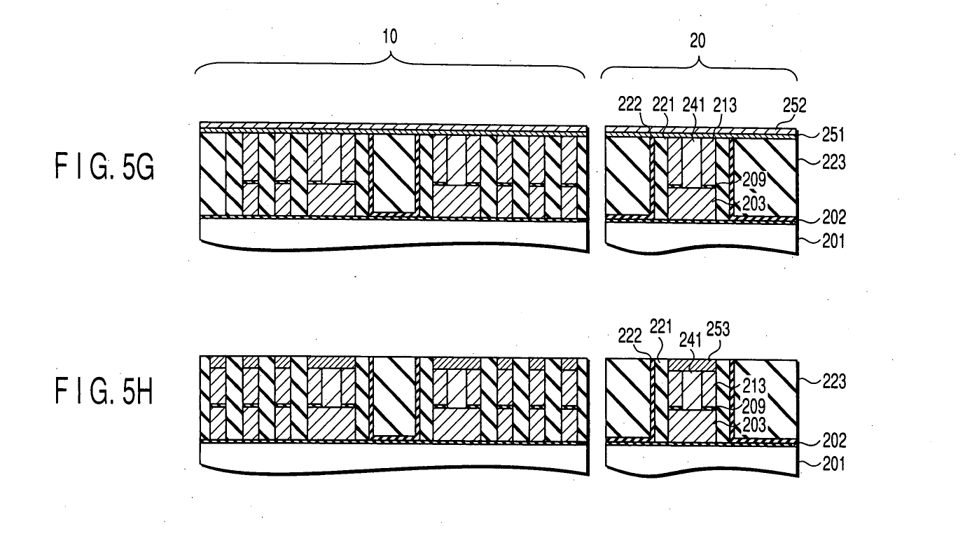

FIGS. 4A to 4M are sectional views showing manufacturing steps of a NAND type nonvolatile semiconductor memory according to a first embodiment. These are sectional views taken along the Y-Y′ line of FIG. 1.

Manufacturing is carried out in the same manner as that mentioned above until the structure shown in FIG. 3B is obtained. Thereafter, as shown in FIG. 4A, the phosphorus doped polysilicon film 113 of 80 nm thick is deposited by an LP-CVD method and the tungsten silicide film 114 of 100 nm thick is deposited on the film 113 by a sputtering method. Furthermore, the silicon nitride film 115 of 200 nm thick is deposited by an LP-CVD method.

Subsequently, as shown in FIG. 4B, the resist pattern 117 for processing gate wiring is lithographically formed. Thereafter, as shown in FIG. 4C, the silicon nitride film 115 is dry-etched with the resist pattern 117 used as a mask, and then the resist pattern 117 is removed by an ashing method.

As shown in FIG. 4D, the tungsten silicide film 114 and phosphorus doped polysilicon film 113 are dry-etched with the silicon nitride film 115 used as a mask. During the dry etching, the ONO film 109 acts as a stopper film.

Subsequently, as shown in FIG. 4E, the ONO film 109 is dry-etched and further the phosphorus doped polysilicon film 103 is dry-etched followed by forming a source and drain diffusion layer (not shown).

Subsequently, as shown in FIG. 4F, the silicon oxide film 121 of 60 nm thick is deposited by an LP-CVD method, and then, the entire resultant structure is etched back by dry-etching with the silicon substrate 101 used as a stopper. As a result, the silicon oxide film 121 is buried in the spaces between adjacent gates and remains as the side walls of gates in the selective transistor region and the peripheral transistor region. Thereafter, the surface of the silicon substrate 101 exposed above is oxidized by heat treatment in an oxidative atmosphere.

Next, as shown in FIG. 4G, the silicon nitride film 122 of 20 nm thick is deposited by an LP-CVD method. Note that the silicon nitride film 122 is also used as an etching stopper when bit line contact and source line contact are formed.

Subsequently, as shown in FIG. 4H, after the silicon oxide film 123 of 700 nm thick is deposited by an LP-CVD method, the silicon oxide film 123 is polished by a CMP method with the silicon nitride film 122 used as a stopper. As a result, the surface of the device is planarized.

Then, as shown in FIG. 4I, a resist pattern 124 for removing the ONO film 109 is lithographically formed on the selective transistors and the peripheral transistor. The removal of the ONO film 109 is performed in order to bring the floating gate and control gate electrically in contact with each other in each of the selective transistors and the peripheral transistor.

Next, as shown in FIG. 4J, the silicon nitride films 122 and 115, the tungsten silicide film 114, and phosphorus-doped polysilicon film 113 are-removed by dry-etching with the resist pattern 124 used as a mask. Subsequently, the ONO film 109 thus exposed is removed by etching.

As shown in FIG. 4K, the resist pattern 124 is removed by an ashing method. Thereafter, as shown in FIG. 4L, a titanium film 131 and a titanium nitride film 132 of 20 nm thick each are separately deposited by sputtering and further a tungsten film 133 of 150 nm thick is deposited by a P-CVD method.

Next, as shown in FIG. 4M, the tungsten film 133, titanium nitride film 132, and titanium film 131 are polished by a CMP method with the silicon nitride film 122 and silicon oxide film 123 used as a stopper.

Note that, in each of the memory cell, selective transistor and peripheral transistor regions, a source and drain diffusion layer is formed at both sides of a gate portion, and adjacent ones are mutually connected in the memory cell and selective transistor regions. In this manner, a NAND cell unit is formed as a memory cell unit. Furthermore, in selective transistors at the drain side and source side of the NAND cell unit, the silicon oxide film 123 and silicon nitride film 122 are selectively etched to form a bit line contact and source line contact, respectively.

In the steps mentioned above, the floating gate and control gate are electrically in contact with each other via the barrier metal and tungsten plug in the selective transistor and peripheral transistor. Therefore, wiring resistance can be reduced. Since the lithography for forming the contact portion between the floating gate and control gate is carried out after lithography for forming the gate wiring, the lithographic pattern for forming the contact portion can be directly aligned with the gate wiring already formed. Therefore, the alignment accuracy of lithographic patterns can be increased compared to a conventional method. As a result, the alignment margin can be reduced, contributing to the reduction of a chip size and manufacturing cost.

### Second Embodiment

FIGS. 5A to 5H are sectional views showing the manufacturing steps of a NAND type nonvolatile semiconductor memory according to a second embodiment. These are sectional views taken along the Y-Y′ line of FIG. 1. Reference numerals 201 to 224 in FIGS. 5A to 5H correspond to reference numerals 101 to 124 of FIGS. 4A to 4M.

The steps until the structure shown in FIG. 5A is obtained are basically the same as those until the structure shown in FIG. 4I of the first embodiment is obtained. The structure of the second embodiment differs from that of the first embodiment in that a phosphorus-doped polysilicon film 213 of 200 nm thick is formed in place of the tungsten silicide film 114.

Thereafter, as shown in FIG. 5B, silicon nitride films 222 and 215 and the phosphorus-doped polysilicon film 213 are removed by dry-etching with a resist pattern 224 used as a mask. Subsequently, as shown in FIG. 5C, the resist pattern 224 is removed by an ashing method.

Subsequently, as shown in FIG. 5D, the entire structure is etched back by dry etching until the upper surface of the phosphorus-doped poly silicon film 213 is exposed under the condition that the etching rate of a silicon nitride film is virtually equal to that of a silicon oxide film. During the etch-back step, an ONO film 209 exposed in the open portion of the phosphorus doped polysilicon film 213 is also etched.

Subsequently, as shown in FIG. 5E, a phosphorus-doped polysilicon film 241 is deposed over the entire surface of the construct by an LP-CVD method and then, as shown in FIG. 5F, the surface phosphorus doped-polysilicon film 241 is removed by a CMP method with the silicon oxide films 221 and 223 used as a stopper.

Subsequently, as shown in FIG. 5G, a cobalt film 251 and a titanium nitride film 252 are deposited over the entire surface of the resultant construct by a sputtering method and then, as shown in FIG. 5H, heat treatment is applied to form a cobalt silicide film 253 on the surface of the phosphorus-doped polysilicon films 213 and 241. Thereafter, unreacted portions of the cobalt film 251 and titanium nitride film 252 are removed by wet etching.

In the aforementioned steps, a floating gate and a control gate are electrically in contact with each other by the phosphorus doped polysilicon film 241 in the selective transistors and peripheral transistor. As a result, the wiring resistance can be reduced. In addition, lithography for forming the contact portion between the floating gate and the control gate is performed after the lithography for forming gate wiring. As a result, the lithographic pattern for forming the contact portion can be directly aligned with the gate wiring already formed. Accordingly, the same effect as that of the first embodiment can be obtained. In addition, the control gate portion is formed of the phosphorus-doped polysilicon film 213 alone, it is not necessary to etch the tungsten silicide film when the portion of the control gate is etched. Hence, the second embodiment has an advantage in that the etching for the control gate portion becomes easy compared to the first embodiment.

### Third Embodiment

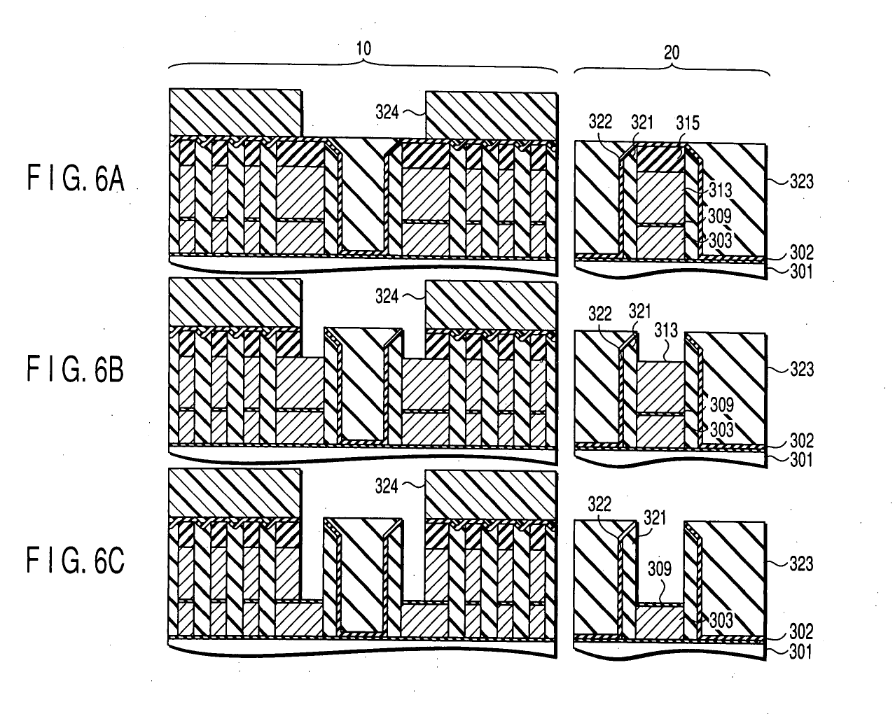

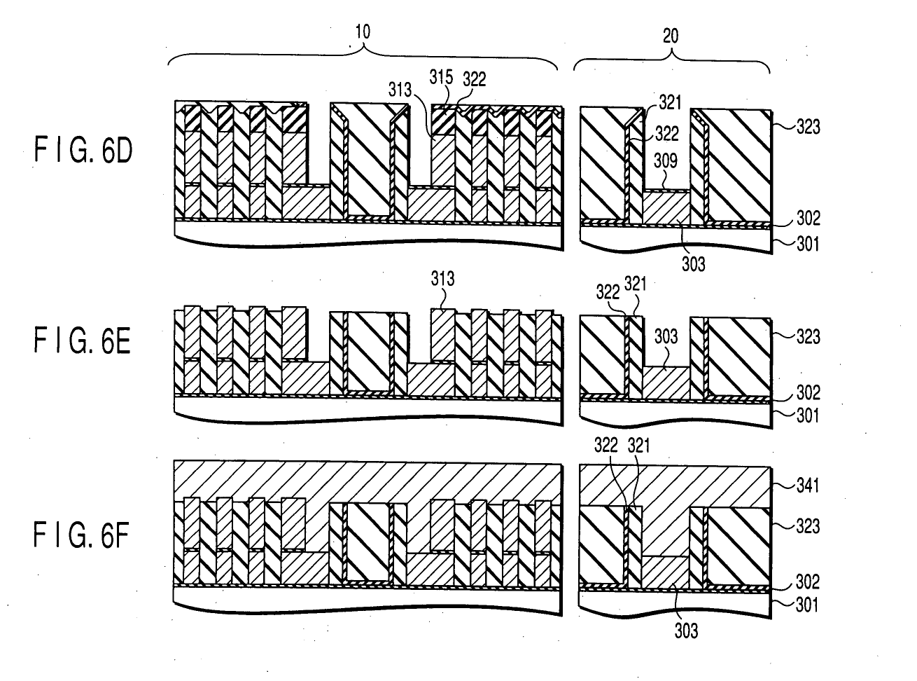

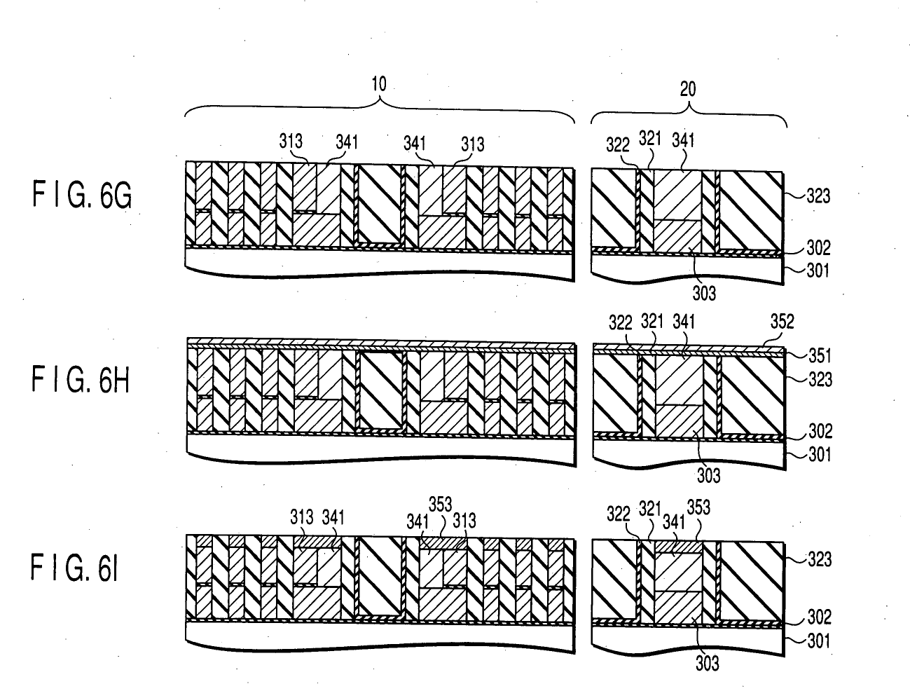

FIGS. 6A to 6I are sectional views showing a NAND type nonvolatile semiconductor memory in a manufacturing step according to a third embodiment. These are sectional views taken along the Y-Y′ line of FIG. 1. Reference numerals 301 to 353 in FIGS. 6A to 6I correspond to reference numerals 201 to 253 of FIGS. 5A to 5H.

The steps until the structure shown in FIG. 6A is obtained are basically the same as those until the structure shown in FIG. 5A is obtained in the second embodiment. Although the resist pattern 224 shown in FIG. 5A has slit-form openings on the selective transistor and peripheral transistor, the resist pattern 324 shown in FIG. 6A has a large opening over two selective transistors and is not formed on the peripheral transistor.

Thereafter, as shown in FIG. 6B, silicon nitride films 322 and 315 are removed by dry-etching with the resist pattern 324 used as a mask. Subsequently, as shown in FIG. 6C, a phosphorus-doped polysilicon film 313 is removed by dry-etching. Thereafter, as shown in FIG. 6D, the resist pattern 324 is removed by an ashing method.

Subsequently, as shown in FIG. 6E, the entire structure is etched back by dry etching until the upper surface of the phosphorus-doped poly silicon film 313 is exposed under the condition that the etching rate of a silicon nitride film is virtually equal to that of a silicon oxide film. During the etch-back step, an ONO film 309 exposed in the open portion of the phosphorus doped polysilicon film 313 is simultaneously etched.

Subsequently, as shown in FIG. 6F, a phosphorus-doped polysilicon film 341 is deposed over the entire surface of the resultant construct by an LP-CVD method and then, as shown in FIG. 6G, the surface phosphorus doped-polysilicon film 341 is removed by a CMP method with the silicon oxide films 321 and 323 used as a stopper.

Subsequently, as shown in FIG. 6H, a cobalt film 351 and a titanium nitride film 352 are deposited over the entire surface of the construct by a sputtering method, and then, as shown in FIG. 6I, heat treatment is applied to form a cobalt silicide film 353 on the surface of the phosphorus-doped polysilicon films 313 and 341. Thereafter, unreacted cobalt film 351 and titanium nitride film 352 are removed by wet etching.

In the aforementioned steps, a floating gate and a control gate are electrically in contact with each other by the phosphorus doped polysilicon film 341 in the selective transistors and peripheral transistor. As a result, the wiring resistance can be reduced. In addition, lithography for forming the contact portion between the floating gate and the control gate is performed after the lithography for forming the gate wiring. As a result, the lithographic pattern for forming the contact portion can be directly aligned with the gate wiring already formed. Accordingly, the same effect as that of the first and second embodiments can be obtained.

In addition, compared to the second embodiment, it is not necessary to form fine slits in the resist pattern 324 on a floating gate and a control gate in the lithographic step of forming the contact portion between a floating gate and a control gate in this embodiment. Therefore, this embodiment is advantageous in that lithography is performed easily. Consequently, the size of the selective transistor and the space between the selective transistors can be reduced. Therefore, a chip size can be reduced more, thereby reducing the cost.

Since the contact area between the phosphorus doped polysilicon film 303 serving as a floating gate and the phosphorus doped polysilicon film 341 serving as a contact portion can be increased, the contact resistance can be reduced.

### MODIFIED EXAMPLE

The present invention is not limited to the aforementioned embodiments. Although a NAND type nonvolatile semiconductor memory has been explained in the embodiments; however, the present invention can be applied to various nonvolatile semiconductor memories having memory cells, a selective transistor or a peripheral transistor. Film materials and thickness thereof, etc., can be appropriately modified depending upon specifications.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-14. (canceled)

15. A method of manufacturing a semiconductor device, comprising:
stacking a first gate insulating film, a first conductive film serving as a floating gate, a second gate insulating film, and a second conductive film serving as a control gate on a semiconductor substrate, thereby forming a gate wiring pattern of a stacked gate structure;
removing part of the second conductive film and the second gate insulating film, thereby forming a contact hole reaching an upper surface of the first conductive film from an upper surface of the second conductive film; and
burying a third conductive film in the contact hole.

16. The method according to claim 15, wherein the contact hole is formed after an insulating film for planarization is buried in a space in the gate wiring pattern.

17. A method of manufacturing a semiconductor device, comprising:
forming a first conductive film serving as a floating gate on a semiconductor substrate via a first gate insulating film;
selectively etching the first conductive film serving as the floating gate so as to remove at least an unnecessary portion in a gate-width direction of the floating gate,
forming a second conductive film serving as a control gate on the substrate and on the first conductive film via a second gate insulating film;
selectively etching the second conductive film together with the first conductive film, thereby forming a gate wiring pattern for each of a nonvolatile semiconductor memory cell and a transistor other than the memory cell;
selectively etching the second conductive film and second gate insulating film by lithography in accordance with the gate wiring pattern in the transistor other than the memory cell, thereby forming a contact hole reaching an upper surface of the first conductive film from an upper surface of the second conductive film; and
burying a third conductive film in the contact hole.

18. The method according to claim 17, wherein the contact hole is formed after an insulating film for planarization is buried in a space in the gate wiring pattern.

19. The method according to claim 18, wherein, after the insulating film for planarization is buried in the space in the gate wiring pattern, a resist pattern is formed which has an opening in which part of the gate wiring pattern including one side thereof is exposed in a selective transistor region of the nonvolatile semiconductor memory cell, and then etching is performed for forming the contact hole with the resist pattern used as a mask.

20. The method according to claim 18, wherein, after the insulating film for planarization is buried in the space in the gate wiring pattern, a resist pattern is formed which has an opening in which the entire gate wiring pattern is exposed in a predetermined peripheral transistor region, and then etching is performed for forming the contact hole with the resist pattern used as a mask.
